(19) United States
(12) Patent Application Publication
(10) Pub. No.: US 2017/0032964 A1
(43) Pub. Date: Feb. 2, 2017

(54) Method for Protecting a Surface of a Substrate and Semiconductor Device

(71) Applicant: Infineon Technologies AG, Neubiberg (DE)

(72) Inventors: Daniel Kueck, Villach (AT); Guenter Denifl, Annenheim (AT); Werner Eigler, Villach (AT); Roland Moennich, Klagenfurt (AT)

(21) Appl. No.: 15/215,334

(22) Filed: Jul. 20, 2016

(30) Foreign Application Priority Data
Jul. 22, 2015 (DE) 102015111891.2

(51) Int. Cl. H01L 21/04; H01L 29/06; H01L 29/16

(52) U.S. Cl. CPC H01L 21/045; H01L 29/1608; H01L 29/0692; H01L 21/0475; H01L 21/046; H01L 21/0485

(57) ABSTRACT

A Method for protecting a surface of a substrate includes processing the substrate, forming a pyrolytic carbon layer on at least one surface of the substrate, and subjecting the substrate to thermal treatment, specifically above a temperature of about 1300° C., typically above about 1400° C.

### PRIORITY CLAIM

This application claims priority to German Patent Application No. 10 2015 111 891.2 filed on 22 Jul. 2015, the content of said application incorporated herein by reference in its entirety.

### BACKGROUND

Embodiments described herein relate to methods for protecting a surface of a semiconductor device and semiconductor devices.

### SUMMARY

According to an embodiment, a method for protecting a surface of a substrate includes processing the substrate: forming a pyrolytic carbon layer on at least one surface of the substrate; and subjecting the substrate to thermal treatment, specifically above a temperature of about 1300° C., typically above about 1400° C.

According to an embodiment, a semiconductor device has a substrate, wherein the substrate includes a first doping area doped with dopants of a first conductivity type; and a second doping area doped with dopants of a second conductivity type, the first doping area and the second doping area forming a pn-junction, wherein a surface of the substrate has a root mean squared surface roughness R_{RMS} of less than about 1 nm, specifically less than about 0.5 nm, in particular about 0.3 nm.

According to an embodiment, a method for forming a doping area includes: providing a SiC substrate having a surface; doping the SiC substrate with a dopant to form a doping area; forming a pyrolytic carbon layer on at least one surface of the substrate, wherein the pyrolytic carbon layer is formed in an inert atmosphere containing a gaseous hydrocarbon precursor, at a deposition temperature in a range of about 600° C. to about 1000° C., and at a deposition pressure of about 133 Pa to 13300 Pa; and subjecting the substrate comprising the pyrolytic carbon layer to a thermal treatment at a deposition temperature of more than about 1300° C.

Those skilled in the art will recognize additional features and advantages upon reading the following detailed description, and upon viewing the accompanying drawings.

### BRIEF DESCRIPTION OF THE DRAWINGS

The components in the figures are not necessarily to scale, instead emphasis being placed upon illustrating the principles of the invention. Moreover, in the figures, like reference signs designate corresponding parts.

FIG. 1A illustrates a semiconductor device according to an embodiment.

FIG. 1B illustrates a semiconductor device according to an embodiment.

FIG. 2 illustrates a scanning electron microscope (SEM) image of a surface of a substrate showing step-bunching.

FIGS. 3A to 3F illustrate a process for protecting a surface of a substrate according to an embodiment.

FIG. 4 illustrates an atomic force microscopy (AFM) image of an AFM analysis of a protected surface of a substrate according to an embodiment.

FIG. 5 illustrates a flow chart of a process for protecting a surface of a substrate according to an embodiment.

### DETAILED DESCRIPTION

In the following Detailed Description, reference is made to the accompanying drawings, which form a part hereof, and in which are shown by way of illustration specific embodiments in which the invention can be practiced. In this regard, directional terminology, such as “top”, “bottom”, “front”, “back”, leading”, “trailing”, “lateral”, “vertical” etc., is used with reference to the orientation of the Figure(s) being described. These terms are intended to encompass different orientations of the device in addition to different orientations than those depicted in the figures. Because components of embodiments can be positioned in a number of different orientations, the directional terminology is used for purpose of illustration and is in no way limiting. Further, terms such as “first”, “second”, and the like, are also used to describe various elements, regions, sections, etc. and are also not intended to be limiting. Like terms refer to like elements throughout the description. It is to be understood that other embodiments can be utilized and structural or logical changes can be made without departing from the scope of the present invention. The following detailed description, therefore, is not to be taken in a limiting sense, and the scope of the present invention is defined by the appended claims. The embodiments being described use specific language, which should not be construed as limiting the scope of the appended claims.

In this specification, a second surface of a semiconductor substrate is considered to be formed by the lower or back-side surface while a first surface is considered to be formed by the upper, front or main surface of the semiconductor substrate. The terms “above” and “below” as used in this specification therefore describe a relative location of a structural feature to another structural feature with consideration of this orientation.

The terms “electrical connection” and “electrically connected” describes an ohmic connection between two elements.

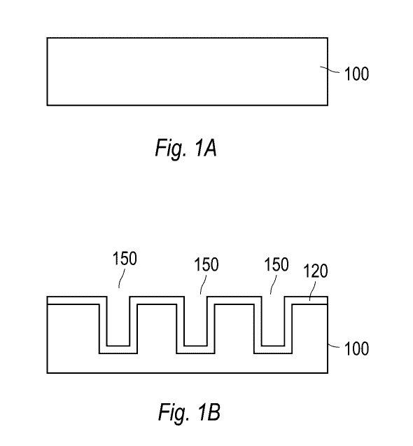

An embodiment is described next with reference to FIG. 1A. With reference to FIG. 1A, a semiconductor device 100 is shown.

The semiconductor device 100 can be made of any semiconductor material suitable for manufacturing semiconductor components. Examples of such materials include, without being limited thereto, elementary semiconductor materials such as silicon (Si), group IV compound semiconductor materials such as silicon carbide (SiC) or silicon germanium (SiGe), binary, ternary or quaternary III-V semiconductor materials such as gallium arsenide (GaAs), gallium phosphide (GaP), indium phosphide (InP), gallium nitride (GaN), aluminium gallium nitride (AlGaN), indium gallium phosphide (InGaPa) or indium gallium arsenide phosphide (InGaAsP), and binary or ternary II-VI semiconductor materials such as cadmium telluride (CdTe) and mercury cadmium telluride (HgCdTe) to name few. The above mentioned semiconductor materials are also referred to as homojunction semiconductor materials. When combining two different semiconductor materials a heterojunction semiconductor material is formed. Examples of heterojunction semiconductor materials include, without being limited thereto, silicon (SiₓC₁₋ₓ) and SiGe heterojunction semiconductor material. For, e.g., power semiconductor applications currently mainly Si, SiC and GaN materials are used. According to an embodiment, which can be combined with other embodiments, the semiconductor 100 is made of SiC.

The semiconductor device 100 includes a substrate 101. Although not shown, the semiconductor device 100 can include one or more doping areas doped with dopants of same or different conductivity type. For instance, the semiconductor device 100 can include a first doping area doped with dopants of a first conductivity type, and a second doping area doped with dopants of a second conductivity type. The first doping area and the second doping area can form a pn-junction. Further, the semiconductor device 100 can include a third doping area doped with dopants of the first conductivity type, a gate insulating layer and a gate electrode forming a MOSEFT.

In the context of the present specification, the term “MOS” (metal-oxide-semiconductor) should be understood as including the more general term “MIS” (metal-insulator-semiconductor). For example, the term MOSFET (metal-oxide-semiconductor field-effect transistor) should be understood to also include FETs having a gate insulator that is not an oxide, i.e. the term MOSFET is used in the more general term meaning of IGFET (insulated-gate field-effect transistor) and MISFET (metal-insulator-semiconductor field-effect transistor), respectively. The term “metal” for the gate material of the MOSFET should be understood to include electrically conductive materials such as, but not restricted to, metal, alloys, doped polycrystalline semiconductors and metal semiconductor compounds such as metal silicides.

Field-effect controlled switching devices such as Metal Oxide Semiconductor Field-effect Transistors (MOSFETs) or Insulated Gate Bipolar Transistors (IGBTs) have been used for various applications, including use as switches in power supplies and power converters, electric cars, air-conditioners, and even stereo systems. Particularly with regard to power devices capable of switching large currents and/or operating at higher voltages, a low resistance in the conducting on-state is often desired. This means e.g. that, for a given current to be switched, the voltage drop across the switched on FET, e.g., the source-drain voltage is desired to be low. On the other hand, the losses occurring during switching off or commutating of the FET are often also to be kept small to minimize the overall losses.

Examples of dielectric materials for forming a dielectric region or dielectric layer between the gate electrode and the doped areas include, without being limited thereto, silicon oxide (SiO₂), silicon nitride (Si₃N₄), silicon oxinitride (SiOₓN_{y}), zirconium oxide (ZrO₂), tantalum oxide (Ta₂O₅), titanium oxide (TiO₂) and hafnium oxide (HfO₂), and combinations thereof including stacks of different insulating materials.

As shown in FIG. 1B, the semiconductor device 150 can further include one or more trench structures 150. Each trench structure 150 is formed having an aspect ratio. The aspect ratio can be understood as the ratio of the sizes of a trench structure 150 in different dimensions. Specifically, the aspect ratio of a trench structure 150 can be understood as the ratio of a depth D of the trench structure 150 to a width W of the trench structure 150. The depth D of a trench structure 150 can be defined to be the geometric size of the trench structure 150 perpendicular to a surface 101a of the substrate 101. The width W of a trench structure 150 can be defined to be the geometric size of the trench structure 150 parallel to the surface 101a of the substrate 101. For instance, the trench structures can have an aspect ratio of more than about 5, specifically more than about 10, in particular more than about 20.

According to an embodiment, which can be combined with other embodiments disclosed herein, the substrate 101 can be an off-axis substrate. In the context of the present application, an off-axis substrate can be understood as a substrate having an off-axis orientation, i.e. having a substrate surface which is tilted by a few degrees about a respective crystallographic orientation or crystal orientation. That is, the off-axis substrate is off-oriented with the respective lattice plane. Typically, off-axis substrates are cut along a direction that is tilted by a few degrees with respect to a respective lattice plane (off-axis cut). For instance, the surface of the substrate can be tilted by an angle which is in the range form 1 degree to 10 degrees with respect to the respective crystal orientation. As it will be appreciated by a person skilled in the art, a respective crystal orientation can be expressed, e.g., by the Miller index commonly known in the art. For instance, the off-axis substrate 101 can include SiC or BN (boron nitride). Specifically, the off-axis substrate 101 is a SiC substrate.

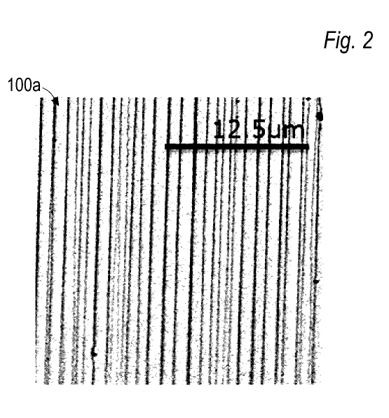

As mentioned above, the substrate 101 can include one or more doping areas doped with dopants. Normally, the substrate 101 is subjected to a heat treatment or thermal treatment for annealing and/or activation of the dopants. For instance, the substrate is subject to a thermal treatment having a temperature of more than 1000° C., typically about 1600° C. During the thermal treatment, a mobility of the atoms of the substrate 101, in particular at the surface 101a of the substrate 101, is increased. Specifically, due to the off-axis orientation of the substrate 101, the atoms of the substrate 101 at the surface 101a can be rearranged during the thermal treatment. For instance, a phenomenon known as step-bunching as shown in FIG. 2 can occur,

FIG. 2 shows a scanning electron microscope (SEM) image of a surface 101a of an off-axis substrate 101 such as a SiC substrate after thermal treatment. The surface 101a includes a plurality of terrace-like structures exposing different lattice planes. This step-bunched surface has different surface properties as the surface 101a before thermal treatment. For instance, the growth condition of layers to be formed on the surface 101a is altered. Accordingly, there is a need for protecting the surfaces of an off-axis substrate during thermal treatment.

According to an embodiment, a carbon layer is used to protect a surface of a substrate. Specifically, the carbon layer is formed on the surface to be protected before the thermal treatment and can be removed thereafter. Conventionally, the carbon layer is formed by forming a polymer layer, such as a photo resist, and baking the polymer layer to outgas solvents and other volatiles from the polymer layer in a furnace by temperature. Thereby, the polymer layer is densified and a graphite or carbon layer is formed.

However, during outgassing of the solvents and volatiles, a volume of the polymer layer can decrease to about the half volume of the polymer layer before baking. Accordingly, the polymer layer is formed thick enough in the beginning to avoid formation of holes in the resulting carbon layer. Further, even though the polymer layer is outgassed as described above, solvents and other volatiles can remain in the carbon layer. These remaining solvents and/or volatiles can outgas during the thermal treatment, e.g., for activating the dopants as described above. For instance, the processing atmosphere during the thermal treatment can be altered by the outgassed solvents and/or volatiles and/or the outgassed solvents and/or volatiles can be deposited in a processing chamber, in which the thermal treatment is performed, whereby component such as valves of the processing chamber can be deteriorated or damaged.

Alternatively, the carbon layer can be DC sputtered or formed by plasma DLC (diamond like carbon). However, sputtering is only useful for covering structured surfaces of substrates as long as an aspect ratio of the structures on or in the substrate is smaller than a critical value. For DC sputtering or plasma DLC, the critical value can be about 3 to 4. Above the critical value, a deposited carbon layer cannot sufficiently cover all structures.

According to an embodiment, a carbon layer is formed as a pyrolytic carbon layer. In the context of the present application, a pyrolytic carbon layer can be understood as a layer formed of pyrolytic carbon. Herein, pyrolytic carbon can be understood as a solid form of carbon which is deposited on a surface during a treatment by pyrolysis of fluid carbon. For instance, pyrolytic carbon can be produced by heating a hydrocarbon, specifically a hydrocarbon expressed by the general formula CₓH_{y}, wherein x and y are positive integers, precursor to its decomposition temperature, and permitting the graphite to crystallize on the surface. Further, the pyrolytic carbon can be formed or deposited from a gaseous phase in an inert atmosphere,

In the context of the present application, the adjective “fluid” can be understood as relating to a fluid, i.e. a liquid or a gas. Accordingly, a fluid object, such as the above “fluid carbon”, my either be liquid or gaseous. Hence, a term “fluid carbon” can be understood by the person skilled in the art as a material that includes carbon and that is in a liquid or gaseous state.

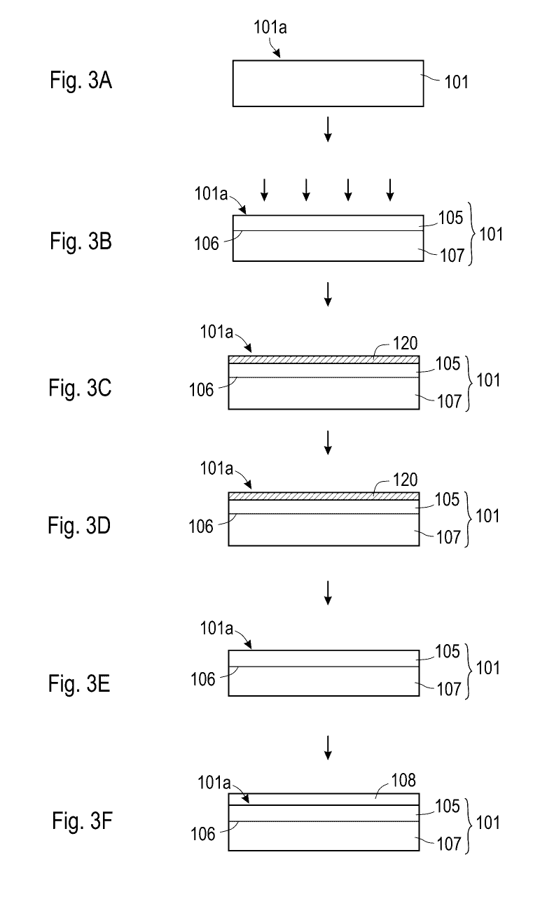

FIGS. 3A to 3F show a process for protecting a surface of a substrate. This process can be a part of a method for manufacturing a semiconductor device such as formation of a power device. Examples are power diodes, power FETs and power IGBTs.

FIG. 3A shows a substrate 101 having a surface 101a. The substrate 101 can be any suitable semiconductor material. Specifically, the substrate 101 is an off-axis substrate as describes above. Typically, the substrate 101 is a SiC substrate. Although not shown, the substrate 101 can include trench structures 150 as shown in FIG. 1B. According to an embodiment, which can be combined with other embodiments, the trench structures have an aspect ratio of more than about 5, specifically more than about 10, in particular more than about 20.

As shown in FIG. 3B, the substrate 101 is subjected to a doping process from the surface 101a. According to an embodiment, which can be combined with other embodiments, the substrate 101 is doped with a dopant in a doping area. Typically, dopants are, e.g., implanted by an ion implantation process to form one or more doping areas in the substrate 101. For instance, the substrate 101 can be doped with a dopant of a first conductivity type in a first doping area, and the substrate 101 can be doped with a dopant of a second conductivity type in a second doping area. The first doping area and the second doping area can form a pn-junction. FIG. 3B illustrates the formation of a doping area 105 that forms a pn-junction 106 with a doping area 107 provided by the substrate 101.

Although a doping process has been described above, it is possible to use any process applied during semiconductor device fabrication can be performed instead or additionally. According to an embodiment, which can be combined with other embodiments, the substrate is processed, specifically by a process used in semiconductor device fabrication.

According to an embodiment shown in FIG. 3C, which can be combined with other embodiments, a pyrolytic carbon layer 120 is formed or deposited at least on the surface 101a. According to an embodiment, which can be combined with other embodiments, the pyrolytic carbon layer 120 can be formed to a thickness of about a few nanometers, such as, e.g., about 0.5 nm to about 50 nm specifically about 1 nm to about 15 nm, typically about 3 nm to about 7 nm, for instance about 5 nm. According to an embodiment, which can be combined with other embodiments, the pyrolytic carbon layer 120 can be formed to such a thickness that a conformity of the pyrolytic carbon layer 120 can be achieved, i.e. that the pyrolytic carbon layer 120 can be formed as a closed layer. For instance, e.g. in case of a graphene, even a monolayer can provide a closed or conformal layer. Hence it will be understood by those having ordinary skill in the art that a “layer thickness of a few nanometers” can refer to a layer thickness sufficient to provide a conformal layer.

In the context of the present application, pyrolytic carbon can be understood as a form of solid carbon having mainly or substantially exclusively sp² hybridized carbon atoms, and having a short-rang order similar to graphite. Typically, pyrolytic carbon has a single cleavage plane, similar to mica, because the graphene sheets crystallize in a planar order, as opposed to graphite, which forms microscopic randomly oriented zones. Further, the pyrolytic carbon layer 120 can be formed with a turbostratic microstructure.

In the context of the present application, “turbostratic microstructure” can be understood as describing a crystal structure in which basal planes have slipped out of alignment. Specifically, the pyrolytic carbon layer 120 can include one or more planes or sub-layers or atomic layers, among which adjacent layers or layers lying on top of each other can be parallel but do not have a preferred orientation with respect to each other. That is, the pyrolytic carbon layer 120 can include, on the nanometer scale, regions in which the planes or sub-layers or atomic layers are almost parallel and equidistant. These planes or sub-layers or atomic layers are however distorted and/or shifted with respect to each other and can include a waviness. According to an embodiment, which can be combined with other embodiments, the pyrolytic carbon layer 120 is formed with a nanocrystalline structure. According to an embodiment, which can be combined with other embodiments, the pyrolytic carbon layer 120 is formed with a grain size or crystal size of about 1 nm to about 20 nm, specifically about 3 nm to about 10 nm, in particular about 5 nm. Further, the pyrolytic carbon layer 120 can adhere very well on the substrate 101, specifically on a SiC substrate.

Hence, pyrolytic carbon can exhibit several unusual anisotropic properties. For instance, pyrolytic carbon layer 120 can be more thermally conductive along the cleavage plane than graphite, making it a very good planar thermal conductor. Further, the pyrolytic carbon layer 120 can have a specific sheet resistance in the range of mOhm·cm. For instance, the pyrolytic carbon layer 120 can have a specific electrical resistivity of about 1 mOhm·cm to about 10 mOhm·cm, specifically from about 1.5 mOhm·cm to about 5 mOhm·cm, typically from about 2 mOhm·cm to about 3 mOhm·cm.

According to an embodiment, which can be combined with other embodiments, the pyrolytic carbon layer 120 is formed on a surface area of the least one surface 101a of the substrate 101 which corresponds to the doping area 105. Specifically, the pyrolytic carbon layer 120 can be formed on the surface area of the surface 101a which faces a doping source. Typically, the surface 101a is the surface of the substrate 101 from which the doping process is performed. Further, the pyrolytic carbon layer 120 can be formed substantially on the entire surface 101a of the substrate. In this context, “entire” or “substantially entire” or “formed substantially on the entire” can be understood as the part of the substrate 101 that is exposed during a thermal treatment, e.g., for activating the dopants. According to embodiments, step bunching can be prevented by covering the area of the substrate 101 that would otherwise be exposed during thermal treatment. This process can be specifically performed without pattering processes such as lithography or shadow masks.

The pyrolytic carbon layer 120 can be deposited on at least the surface 101a of the substrate 101 in a furnace, using a carbon containing material, as a precursor, which can serve as carbon source. Specifically, a fluid hydrocarbon, i.e. a liquid or gaseous hydrocarbon can be used as precursor, such as a liquid or gaseous hydrocarbon according to the generic formula CₓH_{y}. Further, materials not only containing hydrogen and carbon can be used. For instance, materials including hydrogen, carbon and nitrogen, such as pyridine, can be used as precursor. Furthermore, a gas phase deposition technique, such as Low Pressure chemical vapor deposition (LPCVD) or Plasma-enhanced chemical vapor deposition (PECVD), can be used. Depositing a pyrolytic carbon layer on a structured substrate, which can be, e.g., structured with trench structures 150 as described above, can provide be beneficial in that the pyrolytic carbon layer can also be deposited with a high conformity in the trench structures, specifically on side and bottom walls of the trench structures. Specifically, a uniform coverage of the surface 101a of the substrate 101a can be achieved.

According to an embodiment, which can be combined with other embodiments, a fluid hydrocarbon is used as a precursor for forming the pyrolytic carbon layer 120, specifically a carbon containing precursor like ethene, ethane, acetylene, or methane could be used. Further, the precursor can be formed in an inert atmosphere. For instance, the precursor can be diluted in a gas that is inert with respect to the process environment i.e. that does not influence the process carried out. Typically, the precursor can be diluted in an inert gas such as helium (He) or argon (Ar), or can be diluted in nitrogen (N₂).

According to an embodiment, which can be combined with other embodiments, the pyrolytic carbon layer 120 can be formed, e.g. by heating a fluid hydrocarbon, at a deposition temperature of about 500° C. to about 1300° C., specifically about 600° C. to about 950° C., typically about 800° C. to about 900° C. For instance, the pyrolytic carbon layer 120 can be formed or deposited from a gaseous phase, e.g., by LPCVD or PECVD.

According to an embodiment, which can be combined with other embodiments, the pyrolytic carbon layer 120 is formed with a remaining hydrogen concentration of less than about 10 atom %, specifically less than about 7.5 atom %, in particular less than about 5 atom %. That is, the pyrolytic carbon layer 120 can include a remaining hydrogen concentration or remaining hydrogen content of less than about 10 atom %, specifically less than about 7.5 atom %, in particular less than about 5 atom %. Specifically, when using a hydrocarbon as precursor, hydrogen can be generated as side product during deposition of the pyrolytic carbon layer 120. Hydrogen can however not deteriorate the process environment. According to embodiments, the pyrolytic carbon layer 120 can undergo a very small volume loss when thermal treated. For instance, during thermal treatment at a temperature of about 1000° C. the pyrolytic carbon layer 120 can loss about 5% of its volume. Further, outgassing can be reduced or almost prevented during thermal treatment for, e.g., annealing and/or activation of the dopants. Hence, contamination of a processing chamber for performing the thermal treatment can be prevented.

According to an embodiment, which can be combined with other embodiments, the pyrolytic carbon layer 120 is formed under a deposition pressure of about 1 mBar (1 Torr) to about 133 mBar (100 Torr), specifically about 40 mBar (30 Torr) to about 107 mBar (80 Torr), in particular about 67 mBar (50 Torr). According to an embodiment, which can be combined with other embodiments, the pyrolytic carbon layer 120 can be formed at a deposition rate of about 0.1 nm/min to 10 nm/min, specifically about 1 nm/min to about 5 nm/min, in particular about 1.5 nm/min.

For instance, the pyrolytic carbon layer can be formed by a batch process and/or a furnace process. According to an embodiment, which can be combined with other embodiments, the pyrolytic carbon layer is formed by a batch process. Typically, the pyrolytic carbon layer is formed by a batch furnace process.

According to an embodiment shown in FIG. 3D, which can be combined with other embodiments, the substrate 101 is subjected to thermal treatment to activate the dopants. As outlined above, by covering the surface 101a of the substrate 101 with the pyrolytic carbon layer 120, occurring of step-bunching can be prevented.

According to an embodiment shown in FIG. 3E, which can be combined with other embodiments, the pyrolytic carbon layer 120 is removed after subjecting the substrate 101 to thermal treatment.

According to an embodiment, a contact layer or metallization layer 108 is formed on and in ohmic contact with the surface 101a of the substrate 101 to provide an ohmic contact to the doping area 105. The conductive contact layer or metallization layer 108 can be a single layer or a layer stack, and can include metals or metal alloys. It is also possible that the contact layer or metallization layer 108 includes at least one highly doped semiconductor layer.

As outlined above, although a non-structured substrate 101 is shown exemplarily in FIGS. 3A to 3F, person skilled in the art will recognize that the substrate 101 can include trench structures 150 as disclosed with reference to FIG. 1B. According to an embodiment, which can be combined with other embodiments, the substrate 101a is provided with trench structures 150, wherein the trench structures 150 have an aspect ratio of more than about 5, specifically more than about 10, in particular more than about 20. According to an embodiment, the trench structures 150 are formed in the surface 101a of the substrate 101.

According to embodiments described herein, a uniform edge coverage and/or high conformity of the pyrolytic carbon layer 120 can be achieved when depositing the pyrolytic carbon layer 120 as disclosed herein. Hence, trench structures 150 having an aspect ratio as above, specifically the exposed surfaces within the trench structures 150 and the edges between these surfaces, can be covered with high conformity. Hence, occurrence of step-bunching can be prevented also in the trench structures 150. The pyrolytic carbon layer 120 conformally lines the trench structures 150, i.e. covers the sidewalls and the bottoms of the trench structures 150, without completely filling the trench structures 150.

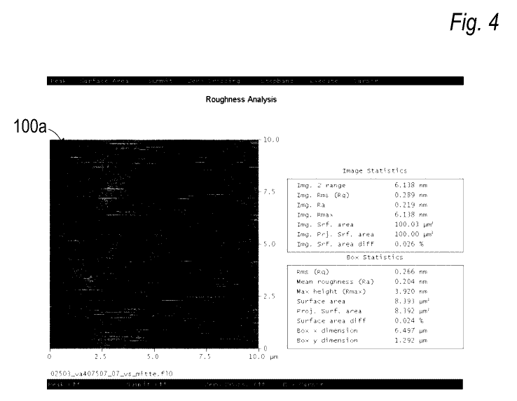

FIG. 4 shows an atomic force microscopy (AFM) image of an AFM analysis of a surface 101a of a substrate 101 that has been protected by a pyrolytic carbon layer 120 during thermal treatment as outlined above. As can be seen from FIG. 4, the surface 101a is uniform, i.e. does not show step-bunching as discussed with reference to FIG. 2. Further, the surface 101a can have a root mean square (RMS) surface roughness R_{RMS} of about 1 nm, specifically less than about 0.5 nm, in particular about 0.3 nm.

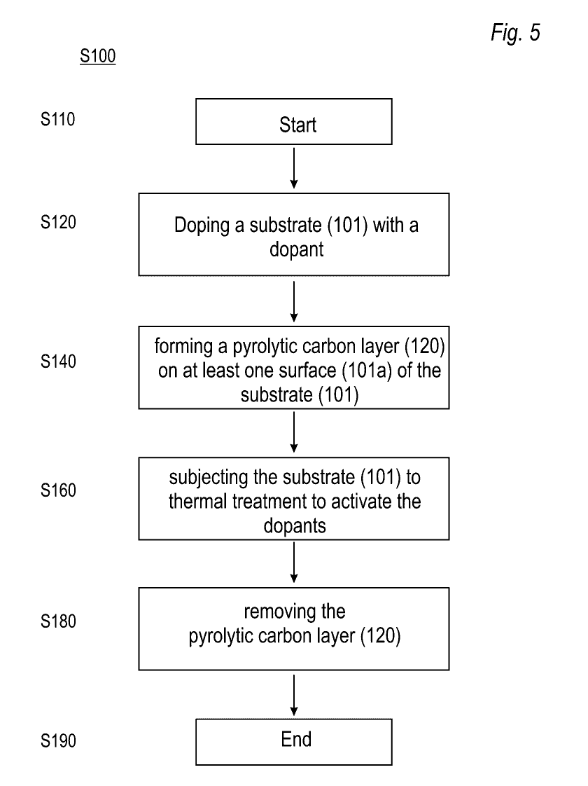

FIG. 5 shows a flow chart of a method S100 for protecting a surface 101a of a substrate 100 according to an embodiment. In block S110, the method is started. In block S120, the substrate 101 is processed. For instance, the substrate 101 can be doped with a dopant. Further, the substrate 101 can be doped with dopants of a first conductivity type in a first doping area, and can be doped with dopants of a second conductivity type in a second doping area. The first doping area and the second doping area can form a pn-junction. In block S140, a pyrolytic carbon layer 120 is formed on at least the surface 101a of the substrate 101. In block S160, the substrate 101 is subjected to a thermal treatment. The thermal treatment can be performed at a temperature of about 1300° C., typically above about 1400° C. Specifically, the temperature used during thermal treatment can be high enough to induce step-bunching in an unprotected surface of the substrate. For instance, the substrate 101 can be subjected to thermal treatment to activate the dopants. Optionally, in block S180, the pyrolytic carbon layer 120 can be removed. The method S100 ends in block S190.

Although a doping process has been described for “processing the substrate”, it will be understood by those having ordinary skill in the art that “processing the substrate” can include any process applied during semiconductor device fabrication. For instance, the fabrication of the trench structures can be one or more processes that fall under the term “processing the substrate”.

According to an embodiment, which can be combined with other embodiments, trench structures 150 are formed in the substrate 101 before forming the pyrolytic carbon layer 120, wherein the trench structures 150 have an aspect ratio of more than about 5, specifically more than about 10, in particular more than about 20.

According to an embodiment, which can be combined with other embodiments, an insulating layer is formed on the at least one surface 101a of the substrate 101 after removing the pyrolytic carbon layer 120. Having protected the surface 101a of the substrate 101a as outlined above, the surface 101a has increased uniformity in terms of, e.g. a low RMS surface roughness R_{RMS}. Accordingly, further layers, such as the insulating layer, can be formed on the surface 101a with an increased stability, providing a reliable semiconductor device. For instance, the substrate 101 being protected as outlined above can be included in or can be a substrate of a power device such as an IGBT (insulated-gate bipolar transistor). Hence, the performance of the power device can be increased.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

With the above range of variations and applications in mind, it should be understood that the present invention is not limited by the foregoing description, nor is it limited by the accompanying drawings. Instead, the present invention is limited only by the following claims and their legal equivalents.

What is claimed is:

1. A method for protecting a surface of a substrate, the method comprising:
processing the substrate;
forming trench structures in the substrate, wherein the trench structures have an aspect ratio of more than about 5;
forming a pyrolytic carbon layer on at least one surface of the substrate, wherein the pyrolytic carbon layer is also deposited into the trench structures to conformally line the trench structure; and
subsequently subjecting the substrate to thermal treatment at a deposition temperature of more than about 1300° C.

2. The method of claim 1, wherein processing the substrate comprises doping the substrate with a dopant to form a doping area, and wherein the substrate is subjected to the thermal treatment to activate the dopants.

3. The method of claim 1, wherein the substrate is a SiC substrate.

4. The method of claim 1, further comprising:
removing the pyrolytic carbon layer after subjecting the substrate to the thermal treatment.

5. The method of claim 1, wherein the pyrolytic carbon layer is formed on a surface area of the at least one surface of the substrate which corresponds to the doping area.

6. The method of claim 1, wherein the pyrolytic carbon layer is formed with a nanocrystalline structure.

7. The method of claim 1, wherein the pyrolytic carbon layer is formed by a batch process.

8. The method of claim 1, wherein a precursor comprising carbon is used for forming the pyrolytic carbon layer.

9. The method of claim 8, wherein the precursor comprises a material having the generic formula CₓH_{y}, wherein x and y are positive integers.

10. The method of claim 8, wherein the precursor is diluted in an inert gas.

11. The method of claim 1, wherein the pyrolytic carbon layer is formed at a deposition temperature of about 600° C. to about 1000° C.

12. The method of claim 1, wherein the pyrolytic carbon layer is formed under a deposition pressure of about 133 Pa (1 Torr) to about 13300 Pa (100 Torr).

13. The method of claim 1, wherein the pyrolytic carbon layer is formed to a thickness of a few nanometers.

14. The method of claim 1, wherein the pyrolytic carbon layer is formed at a deposition rate of about 0.1 nm/min to 10 nm/min.

15. The method of claim 1, wherein the pyrolytic carbon layer is formed with a grain size of about 1 nm to about 20 nm.

16. The method of claim 1, wherein the pyrolytic carbon layer is formed with a remaining hydrogen concentration of less than about 10 atom %.

17. The method of claim 1, further comprising:
forming an insulating layer on the at least one surface of the substrate after removing the pyrolytic carbon layer.

18. A method for forming a doping area, the method comprising:
providing a SiC substrate having a surface;
doping the SiC substrate with a dopant to form a doping area;
forming trench structures in the substrate, wherein the trench structures have an aspect ratio of more than about 5;
forming a pyrolytic carbon layer on the surface of the substrate, wherein the pyrolytic carbon layer is formed in an inert atmosphere containing a gaseous hydrocarbon precursor, at a deposition temperature in a range of about 600° C. to about 1000° C., and at a deposition pressure of about 133 Pa (1 Torr) to 13300 Pa (100 Torr), wherein the pyrolytic carbon layer is also deposited into the trench structures to conformally line the trench structure; and
subjecting the substrate comprising the pyrolytic carbon layer to a thermal treatment at a deposition temperature of more than about 1300° C.

19. The method of claim 18, further comprising:
removing the pyrolytic carbon layer after the thermal treatment.

20. The method of claim 19, further comprising:
forming a conductive contact layer or metallization layer on and in ohmic contact with the doping area after removing the pyrolytic layer.

21. A semiconductor device having a substrate, the substrate comprising:
a first doping area doped with dopants of a first conductivity type;
a second doping area doped with dopants of a second conductivity type, the first doping area and the second doping area forming a pn-junction; and
trench structures having an aspect ratio of more than about 5,
wherein a surface of the substrate has a root mean squared surface roughness R_{RMS} of less than about 1 nm.

22. The semiconductor device of claim 21, wherein the substrate is a SiC substrate.

23. The semiconductor device of claim 21, further comprising:
an insulating layer on at least one surface of the substrate.
